(19) United States
(12) Patent Application Publication
(10) Pub. No.: US 2024/0387622 A1
(43) Pub. Date: Nov. 21, 2024

(54) SEMICONDUCTOR STRUCTURE AND METHOD OF FORMING THE SAME

(71) Applicants: Semiconductor Manufacturing International (Shanghai) Corporation, Shanghai (CN); Semiconductor Manufacturing International (Beijing) Corporation, Beijing (CN)

(72) Inventors: Kuchanuri SUBHASH, Shanghai (CN); Jun WANG, Shanghai (CN); Yang YU, Shanghai (CN)

(21) Appl. No.: 18/686,422

(22) PCT Filed: Aug. 25, 2021
(86) PCT No.: PCT/CN2021/114493

§ 371 Date: Feb. 25, 2024

(51) Int. Cl. H01L 29/06; H01L 21/8234; H01L 27/088; H01L 29/66

(52) U.S. Cl. CPC H01L 29/0649; H01L 21/823481; H01L 27/088; H01L 29/66545

(57) ABSTRACT

Semiconductor structure and method of forming the same are provided. The structure includes a substrate. The substrate includes a first region and a second region arranged along a first direction. The first region includes a first isolation area. The second region includes a second isolation area. A central axis of the first isolation area parallel to the first direction does not coincide with a central axis of the second isolation area parallel to the first direction. The structure also includes a first gate structure on the first region, a first metal layer and a second metal layer on two sides of the first gate structure, a second gate structure on the second region, a third metal layer and a fourth metal layer on two sides of the second gate structure, a first isolation structure on the first isolation area, and a second isolation structure on the second isolation area.

### TECHNICAL FIELD

The present disclosure generally relates to the field of semiconductor manufacturing technology and, more particularly, relates to a semiconductor structure and a method of forming the same.

### BACKGROUND

With continuous development of semiconductor technology, improvement of integrated circuit performance is mainly achieved by continuously reducing size of an integrated circuit device to increase a speed of the device. Nowadays, due to demand for high device density, high performance, and low cost, semiconductor industry has advanced to nanotechnology process nodes.

However, reducing size of a circuit device to increase an integration level is an ongoing issue that needs to be addressed.

### SUMMARY

The present disclosure provides a semiconductor structure and a method of forming the same to reduce size of a circuit device for increasing an integration level.

To solve the above technical problems, the present disclosure provides a semiconductor structure. The semiconductor structure includes: a substrate, where the substrate includes at least one unit area, a unit area of the at least one unit area includes a first region and a second region adjacent to the first region, the first region and the second region are arranged along a first direction, the first region includes a first active area, a first isolation area, and a second active area arranged along a second direction, the first active area and the second active area are located on two sides of the first isolation area, the second region includes a third active area, a second isolation area, and a fourth active area arranged along the second direction, the third active area and a fourth active area are located on two sides of the second isolation area, and a central axis of the first isolation area parallel to the first direction does not coincide with a central axis of the second isolation area parallel to the first direction, the first direction is parallel to a surface of the substrate, and the first direction and the second direction are perpendicular to each other; a first gate structure located on the first region, where the first gate structure spans the first active area, the first isolation area and the second active area; and a first metal layer and a second metal layer respectively located on two sides of the first gate structure, where the first gate structure, the first metal layer, and the second metal layer are parallel to the second direction; a second gate structure located on the second region, where the second gate structure spans the third active area, the second isolation area and the fourth active area; and a third metal layer and a fourth metal layer respectively located on two sides of the second gate structure, where the second gate structure, the third metal layer and the fourth metal layer are parallel to the second direction; a first isolation structure located on the first isolation area, where the first isolation structure penetrates the first metal layer and the second metal layer along the first direction, and the first gate structure is located over the first isolation structure; and a second isolation structure located on the second isolation area, where the second isolation structure penetrates the third metal layer and the fourth metal layer along the first direction, and the second gate structure is located over the second isolation structure.

Optionally, the first isolation area is adjacent to the first active area and the second active area; and the second isolation area is adjacent to the third active area and the fourth active area.

Optionally, a conductivity type of a device in the first active area is opposite to a conductivity type of a device in the second active area, and a conductivity type of a device in the third active area is opposite to a conductivity type of a device in the fourth active area.

Optionally, the first active area and the third active area are adjacent, and the second active area and the fourth active area are adjacent; the conductivity type of the device in the first active area is same as the conductivity type of the device in the third active area, and the conductivity type of the device is N type; the conductivity type of the device in the second active area is same as the conductivity type of the device in the fourth active area, and the conductivity type of the device is P type.

Optionally, the structure also includes a fifth metal layer located on the first region, where the fifth metal layer is located between the second metal layer and the third metal layer, the fifth metal layer is parallel to the second direction, and the first isolation structure also penetrates the fifth metal layer along the first direction.

Optionally, the structure also includes a plurality of dummy gate structures located over the substrate, where the plurality of the dummy gate structures is arranged in parallel, and the plurality of dummy gate structures is parallel to the second direction; the first metal layer is located between a dummy gate structure of the plurality of the dummy gate structures and the first gate structure, the second metal layer is located between the dummy gate structure and the first gate structure, the third metal layer is located between the dummy gate structure and the second gate structure, the fourth metal layer is located between the dummy gate structure and the second gate structure, and the fifth metal layer is located between adjacent dummy gate structures of the plurality of the dummy gate structures.

Optionally, the structure also includes a first connection layer parallel to the first direction, where the first connection layer is electrically connected to the second metal layer, and the fifth metal layer and the third metal layer on the first active area and the third active area; a second connection layer parallel to the first direction, where the second connection layer is electrically connected to the second metal layer and the fifth metal layer on the second active area; a first conductive layer parallel to the first direction, where the first conductive layer spans the first active area and the third active area, and the first conductive layer is electrically connected to the first metal layer on the first active area and the fourth metal layer on the third active area; a second conductive layer parallel to the first direction, where the second conductive layer is electrically connected to the third metal layer on the fourth active area, and the second conductive layer is located on the fourth active area; a third conductive layer parallel to the first direction, where the third conductive layer spans the second active area and the fourth active area, and the third conductive layer is electrically connected to the first metal layer on the second active area and the fourth metal layer on the fourth active area; and an electrical output layer parallel to the second direction, where the electrical output layer is electrically connected to the first conductive layer and the second conductive layer.

Optionally, the structure also includes a fourth conductive layer parallel to the first direction, where the fourth conductive layer is electrically connected to the second gate structure, and the fourth conductive layer spans the first active area and the second isolation area.

Optionally, the first conductive layer, the fourth conductive layer, the second conductive layer and the third conductive layer are sequentially arranged in parallel with an equal interval.

Optionally, the structure also includes a fifth conductive layer parallel to the first direction, where the fifth conductive layer is located on the first isolation area, the fifth conductive layer is electrically connected to the first gate structure, a central axis of the fifth conductive layer in the first direction coincides with a central axis of the second conductive layer in the first direction.

Optionally, the structure also includes a power supply voltage line electrically connected to the fifth metal layer on the first active area; and a ground voltage line electrically connected to the fifth metal layer on the second active area, where the power supply voltage line and the ground voltage line are parallel to the first direction.

Optionally, a plurality of unit areas includes a first unit area and a second unit area, units of the first unit area and the second unit area are arranged along the first direction, the second region of the first unit area is adjacent to the first region of the second unit area, the first active area of the second unit area is adjacent to the third active area of the first unit area, and the second active area of the second unit area is adjacent to the fourth active area of the first unit area.

Optionally, the structure also includes a first connection layer parallel to the first direction, where the first connection layer is electrically connected to the second metal layer, the fifth metal layer and the third metal layer on the first active area and the third active area of the first unit area; a second connection layer parallel to the first direction, where the second connection layer is electrically connected to the second metal layer and the fifth metal layer on the second active area of the first unit area; a third connection layer parallel to the first direction, where a central axis of the third connection layer in the first direction coincides with a central axis of the first connection layer in the first direction, and the third connection layer is electrically connected to the second metal layer and the fifth metal layer on the first active area of the second unit area; and a fourth connection layer parallel to the first direction, where a central axis of the fourth connection layer in the first direction coincides with a central axis of the second connection layer in the first direction, and the fourth connection layer is electrically connected to the second metal layer and the fifth metal layer on the second active area of the second unit area.

Optionally, the structure also includes a first conductive layer located on the first unit area, where the first conductive layer is parallel to the first direction, the first conductive layer spans the first active area and the third active area of the first unit area, and the first conductive layer is electrically connected to the first metal layer on the first active area of the first unit area and the fourth metal layer on the third active area; a second conductive layer located on the fourth active area of the first unit area and the first isolation area of the second unit area, where the second conductive layer is parallel to the first direction, and the second conductive layer is electrically connected to the fourth metal layer on the fourth active area of the first unit area and the first gate structure of the second unit area; a third conductive layer located on the first unit area, where the third conductive layer is parallel to the first direction, the third conductive layer spans the second active area and the fourth active area of the first unit area, and the third conductive layer is electrically connected to the first metal layer on the second active area of the first unit area and the third metal layer on the fourth active area; a fourth conductive layer located on the first unit area, where the fourth conductive layer is parallel to the first direction, the fourth conductive layer is electrically connected to the second gate structure of the first unit area, and the fourth conductive layer spans the first active area and the second isolation area of the first unit area; and a fifth conductive layer located on the first unit area, where the fifth conductive layer is parallel to the first direction, the fifth conductive layer is located on the first isolation area, the fifth conductive layer is electrically connected to the first gate structure of the first unit area, and a central axis of the fifth conductive layer in the first direction coincides with a central axis of the second conductive layer in the first direction.

Optionally, the first conductive layer, the fourth conductive layer, the second conductive layer and the third conductive layer are sequentially arranged in parallel with an equal interval.

Optionally, the structure also includes a sixth conductive layer located on the first active area of the second unit area, where the sixth conductive layer is parallel to the first direction, and the sixth conductive layer is electrically connected to the first metal layer on the first active area of the second unit area; a seventh conductive layer located on the third active area of the second unit area, where the seventh conductive layer is parallel to the first direction, and the seventh conductive layer is connected to the third metal layer and the fourth metal layer on the third active area of the second unit area; an eighth conductive layer located on the second active area of the second unit area, where the eighth conductive layer is parallel to the first direction, and the eighth conductive layer is electrically connected to the first metal layer on the second active area of the second unit area; and a ninth conductive layer located on the fourth active area of the second unit area, where the ninth conductive layer is parallel to the first direction, the ninth conductive layer is electrically connected to the third metal layer and the fourth metal layer on the fourth active area of the second unit area, central axes of the first conductive layer, the sixth conductive layer and the seventh conductive layer in the first direction coincide with each other, and central axes of the third conductive layer, the eighth conductive layer, and the ninth conductive layer in the first direction coincide with each other.

Optionally, the structure also includes a first electrical output layer parallel to the second direction, where the first electrical output layer is electrically connected to the first conductive layer and the second conductive layer on the first unit area; and a second electrical output layer parallel to the second direction, where the second electrical output layer is electrically connected to the sixth conductive layer and the eighth conductive layer on the second unit area.

Optionally, a power supply voltage line electrically connected to the fifth metal layer on the first active area of the first unit area and the fifth metal layer on the first active area of the second unit area; and a ground voltage line electrically connected to the fifth metal layer on the second active area of the first unit area and the fifth metal layer on the second active area of the second unit area, where the power supply voltage line and the ground voltage line each are parallel to the first direction.

Optionally, a plurality of unit areas includes a first unit area, a second unit area, a third unit area and a fourth unit area; the first unit area and the second unit area are arranged along the first direction parallel to the surface of the substrate, and a second region of the first unit area is adjacent to a first region of the second unit area; the third unit area and the fourth unit area are arranged along the first direction parallel to the surface of the substrate, and a second region of the third unit area is adjacent to a first region of the fourth unit area; the first unit area and the fourth unit area are arranged along the second direction parallel to the substrate surface, and the first region of the first unit area is adjacent to the second region of the fourth unit area, and the second region of the first unit area is adjacent to the first region of the fourth unit area; and the second unit area and the third unit area are arranged along the second direction parallel to the surface of the substrate, the second region of the second unit area is adjacent to the first region of the third unit area, and the first region of the second unit area is adjacent to the second region of the third unit area.

Optionally, the structure also includes a first connection layer parallel to the first direction, where the first connection layer is electrically connected to the second metal layer and the fifth metal layer on the first active area; a second connection layer parallel to the first direction, where the second connection layer is electrically connected to the second metal layer and the fifth metal layer on the second active area; a first conductive layer parallel to the first direction, where the first conductive layer is electrically connected to the first metal layer on the first active area; a second conductive layer parallel to the first direction, where the second conductive layer is electrically connected to the first gate structure, and the second conductive layer spans the first active area and the second isolation area; a third conductive layer parallel to the first direction, where the third conductive layer electrically connected to the first metal layer on the second active area; and an electrical output layer parallel to the second direction, where the electrical output layer is electrically connected to the first conductive layer and the third conductive layer.

Optionally, the structure also includes a fourth conductive layer parallel to the first direction, where the fourth conductive layer is electrically connected to the third metal layer and the fourth metal layer on the third active area, and a central axis of the fourth conductive layer in the first direction X coincides with a central axis of the first conductive layer in the first direction; and a fifth conductive layer parallel to the first direction, where the fifth conductive layer is electrically connected to the third metal layer and the fourth metal layer on the fourth active area, and a central axis of the fifth conductive layer in the first direction coincides with a central axis of the third conductive layer in the first direction.

Optionally, the structure also includes a sixth conductive layer parallel to the first direction, where the sixth conductive layer spans the first isolation area and the fourth active area, and the first conductive layer, the second conductive layer, the sixth conductive layer and the third conductive layer are sequentially arranged in parallel with an equal interval; a power supply voltage line parallel to the first direction, where the power supply voltage line is electrically connected to the fifth metal layer on the first active area; and a ground voltage line parallel to the first direction, where the ground voltage line is electrically connected to the fifth metal layer on the second active area.

Correspondingly, the present disclosure also provides a method of forming a semiconductor structure. The method includes: providing a substrate, where the substrate includes at least one unit area, a unit area of the at least one unit area includes a first region and a second region adjacent to the first region, the first region and the second region are arranged along a first direction, the first region includes a first active area, a first isolation area, and a second active area arranged along a second direction, the first active area and the second active area are located on two sides of the first isolation area, the second region includes a third active area, a second isolation area, and a fourth active area arranged along the second direction, the third active area and a fourth active area are located on two sides of the second isolation area, and a central axis of the first isolation area parallel to the first direction does not coincide with a central axis of the second isolation area parallel to the first direction, the first direction is parallel to a surface of the substrate, and the first direction and the second direction are perpendicular to each other; forming a first gate structure located on the first region, where the first gate structure spans the first active area, the first isolation area and the second active area; and a first metal layer and a second metal layer respectively located on two sides of the first gate structure, where the first gate structure, the first metal layer, and the second metal layer are parallel to the second direction; forming a second gate structure located on the second region, where the second gate structure spans the third active area, the second isolation area and the fourth active area; and a third metal layer and a fourth metal layer respectively located on two sides of the second gate structure, where the second gate structure, the third metal layer and the fourth metal layer are parallel to the second direction; forming a first isolation structure located on the first isolation area, where the first isolation structure penetrates the first metal layer and the second metal layer along the first direction, and the first gate structure is located over the first isolation structure; and forming a second isolation structure located on the second isolation area, where the second isolation structure penetrates the third metal layer and the fourth metal layer along the first direction, and the second gate structure is located over the second isolation structure.

In the semiconductor structure provided by the present disclosure, the substrate includes at least one unit area. The unit area includes a first region and a second region adjacent to the first region. The first region and the second region are adjacent along the first direction parallel to a surface of the substrate. The first region includes a first isolation area, and the second region includes a second isolation area. A central axis of the first isolation area parallel to the first direction does not coincide with a central axis of the second isolation area parallel to the first direction. As such, when a conductive layer parallel to the first direction is subsequently formed, under established rules for conductive layer design, a quantity of locations, where the conductive layer may be electrically connected to the first metal layer, the second metal layer, the third metal layer, the fourth metal layer, the first gate structure or the second gate structure, may be increased. As a result, a semiconductor structural unit with a small area may be used to form a complex circuit. Accordingly, area may be saved, flexibility of back-end wiring may be increased, and an integration level may be improved.

Further, the substrate includes a first region and a second region, and the first region and the second region are adjacent along the first direction parallel to the surface of the substrate. The first region includes the first isolation area and the second region includes the second isolation area. The central axis of the first isolation area in the first direction does not coincide with the central axis of the second isolation area in the first direction. As such, the second conductive layer may form an active gate contact electrically connected to the first gate structure on the first active area. Accordingly, area may be saved, and wiring flexibility may be increased.

### BRIEF DESCRIPTION OF THE DRAWINGS

FIG. 1 illustrates a schematic diagram of a semiconductor structural unit;

FIG. 2 illustrates a schematic diagram of a process of forming a semiconductor structure consistent with the disclosed embodiments of the present disclosure;

FIGS. 3-5 illustrate schematic diagrams of another process of forming a semiconductor structure consistent with the disclosed embodiments of the present disclosure;

FIGS. 6-8 illustrate schematic diagrams of another process of forming a semiconductor structure consistent with the disclosed embodiments of the present disclosure;

FIG. 9 illustrates a schematic diagram of another process of forming a semiconductor structure consistent with the disclosed embodiments of the present disclosure; and

FIGS. 10-12 illustrate schematic diagrams of another process of forming a semiconductor structure consistent with the disclosed embodiments of the present disclosure.

### DETAILED DESCRIPTION

As mentioned in the background, reducing a size of a circuit device to increase an integration level is an ongoing issue that needs to be addressed. Analysis and description will now be carried out with reference to specific embodiments.

FIG. 1 illustrates a schematic diagram of a semiconductor structural unit.

Referring to FIG. 1, the semiconductor structural unit includes: a substrate 100, where the substrate 100 includes a first region I, an isolation region III and a second region II arranged along a second direction Y parallel to the substrate; a first gate structure 101, a second gate structure 102 and a dummy gate structure 103 parallel to the second direction Y, where the first gate structure 101, the second gate structure 102 and the dummy gate structure 103 are arranged with an equal interval; a metal layer 104 located on two sides of the first gate structure 101, on two sides of the second gate structure 102, and between adjacent dummy gate structures 103; an isolation structure 105 parallel to the first direction X, where the isolation structure 105 is disposed on the isolation area III and penetrates the metal layer 104, and the first direction X is perpendicular to the second direction Y; a first conductive layer 106 and a second conductive layer 107 parallel to the first direction X, where the first conductive layer 106 spans the first region I, and the second conductive layer 107 spans the second region II.

In the semiconductor structural unit, the isolation region III is located between the first region I and the second region II. Accordingly, under established design rules, only one first conductive layer 106 may be formed on the first region I, and only one second conductive layer 107 may be formed on the first region II. As such, the metal layer 104, the first gate structure 101 and the second gate structure 102 located on the first region I and the second region II respectively may only be connected out through one conductive layer, and selection space may be small. To form a complex circuit structure, a plurality of semiconductor structural units may need to be integrated, and a semiconductor structure formed may have a larger area.

To solve the above problems, the present disclosure provides a semiconductor structure and a method of forming the semiconductor structure. A semiconductor structural unit with a small area may be used to form a complex circuit. Accordingly, area may be saved, flexibility of back-end wiring may be increased, and an integration level may be improved.

To make above objects, features and beneficial effects of the present disclosure more obvious and understandable, specific embodiments of the present disclosure will be described in detail below with reference to accompanying drawings.

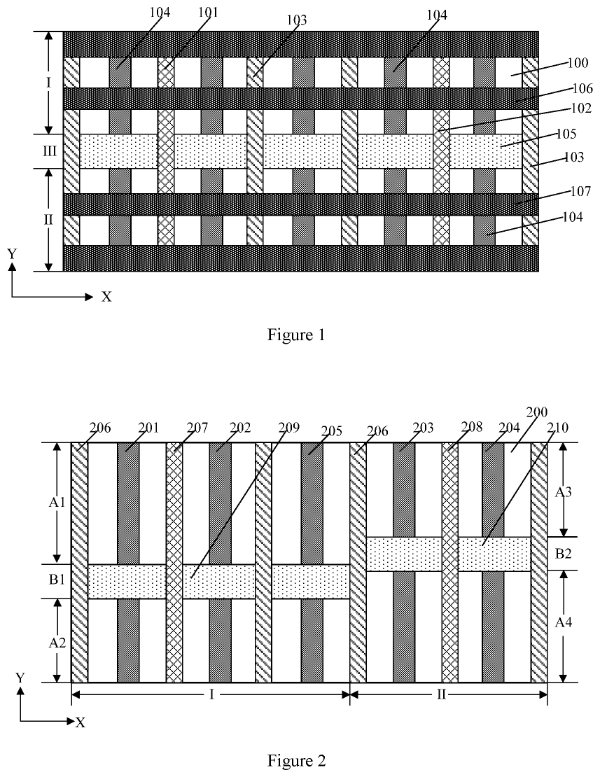

FIG. 2 illustrates a schematic diagram of a process of forming a semiconductor structure consistent with the disclosed embodiments of the present disclosure.

Referring to FIG. 2, the process includes providing a substrate 200. The substrate 200 includes at least one unit area. The unit area includes a first region I and a second region II adjacent to the first region I. The first region I and the second region II are arranged along a first direction X. The first direction X is parallel to a surface of the substrate 200. The first region I includes a first isolation area B1, and the second region II includes a second isolation area B2. A central axis of the first isolation area B1 parallel to the first direction X does not coincide with a central axis of the second isolation area B2 parallel to the first direction X.

The first region I also includes a first active area A1 and a second active area A2. The first isolation area B1 is located between the first active area A1 and the second active area A2. The first isolation area B1 is adjacent to the first active area A1 and the second active area A2. The first active area A1, the second active area A2 and the first isolation area B1 are arranged along the second direction Y. The second region II also includes a third active area A3 and a fourth active area A4. The second isolation area B2 is located between the third active area A3 and the fourth active area A4. The second isolation area B2 is adjacent to the third active area A3 and the fourth active area A4. The third active area A3, the fourth active area A4 and the second isolation area B2 are arranged along the second direction Y.

A conductivity type of a device in the first active area A1 is opposite to a conductivity type of a device in the second active area A2. A conductivity type of a device in the third active area A3 is opposite to a conductivity type of a device in the fourth active area A4.

In one embodiment, the first active area A1 and the third active area A3 are adjacent, and the second active area A2 and the fourth active area A4 are adjacent. The conductivity type of the device in the first active area A1 is same as the conductivity type of the device in the third active area A3, and the conductivity type of the device is N type. The conductivity type of the device in the second active area A2 is same as the conductivity type of the device in the fourth active area A4, and the conductivity type of the device is P type.

Still referring to FIG. 2, the process also includes forming a first gate structure 207, a first isolation structure 209, and a first metal layer 201 and a second metal layer 202 respectively located on two sides of the first gate structure 207, on the first region I. The first gate structure 207 spans the first active area A1, the first isolation area B1 and the second active area A2. The first isolation structure 209 penetrates the first metal layer 201, the second metal layer 202 and a fifth metal layer 205 along the first direction X. The first gate structure 207 is located on the first isolation structure 209. The first isolation structure 209 is located on the first isolation area B1. The first gate structure 207, the first metal layer 201 and the second metal layer 202 are parallel to a second direction Y. The second direction Y is parallel to a surface of the substrate 200 and perpendicular to the first direction X.

Still referring to FIG. 2, the process also includes forming a second gate structure 208, a second isolation structure 210, and a third metal layer 203 and a fourth metal layer 204 respectively located on two sides of the second gate structure 208, on the second region II. The second gate structure 208 spans the third active area A3, the second isolation area B2 and the fourth active area A4. The second gate structure 208 is located on the second isolation structure 210. The second isolation structure 210 is located on the second isolation area B2. The second isolation structure 210 penetrates the third metal layer 203 and the fourth metal layer 204 along the first direction X. The second gate structure 208, the third metal layer 203 and the fourth metal layer 204 are parallel to the second direction Y.

The first metal layer 201, the second metal layer 202, the third metal layer 203 and the fourth metal layer 204 may be formed simultaneously. The first gate structure 207 and the second gate structure 208 may be formed simultaneously.

In one embodiment, while forming the first metal layer 201, the second metal layer 202, the third metal layer 203 and the fourth metal layer 204, the fifth metal layer 205 may also be formed on the first region I. The fifth metal layer 205 is located between the second metal layer 202 and the third metal layer 203, and the fifth metal layer 205 is parallel to the second direction Y.

In one embodiment, while forming the first gate structure 207 and the second gate structure 208, a plurality of dummy gate structures 206 may also be formed on the substrate. The plurality of the dummy gate structures 206 is arranged in parallel, and the plurality of the dummy gate structures 206 is parallel to the second direction Y.

The first metal layer 201 is located between the dummy gate structure 206 and the first gate structure 207. The second metal layer 202 is located between the dummy gate structure 206 and the first gate structure 207. The third metal layer 203 is located between the dummy gate structure 206 and the second gate structure 208. The fourth metal layer 204 is located between the dummy gate structure 206 and the second gate structure 208. The fifth metal layer 205 is located between adjacent dummy gate structures 206.

The dummy gate structure 206 is configured to improve process uniformity of forming the first gate structure 207 and the second gate structure 208.

The central axis of the first isolation area B1 in the first direction X does not coincide with the central axis of the second isolation area B2 in the first direction X. As such, when a conductive layer parallel to the first direction X is subsequently formed, under established rules for conductive layer design, a quantity of locations, where the conductive layer may be electrically connected to the first metal layer 201, the second metal layer 202, the third metal layer 203, the fourth metal layer 204, the fifth metal layer 205, the first gate structure 207 or the second gate structure 208, may be increased. As a result, a semiconductor structural unit with a small area may be used to form a complex circuit. Accordingly, area may be saved, flexibility of back-end wiring may be increased, and an integration level may be improved.

In one embodiment, the process also includes: forming a first dielectric layer (not shown) on the substrate 200. The first metal layer 201, the second metal layer 202, the third metal layer 203, the fourth metal layer 204, the fifth metal layer 205, the dummy gate structure 206, the first gate structure 207 and the second gate structure 208 are located in the first dielectric layer.

Correspondingly, the present disclosure also provides a semiconductor structure. Referring to FIG. 2, the semiconductor structure includes:
a substrate: the substrate 200 includes at least one unit area, and the unit area includes a first region I and a second region II adjacent to the first region I; the first region I and the second region II are arranged along a first direction X, and the first direction X is parallel to a surface of the substrate 200; the first region I includes a first isolation area B1, and the second region II includes a second isolation area B2; and the central axis of the first isolation area B1 parallel to the first direction X does not coincide with the central axis of the second isolation area B2 parallel to the first direction X;
a first gate structure 207 located on the first region I, and a first metal layer 201 and a second metal layer 202 respectively located on two sides of the first gate structure 207: the first gate structure 207, the first metal layer 201 and the second metal layer 202 are parallel to a second direction Y, and the second direction Y is parallel to a surface of the substrate 200 and perpendicular to the first direction X;
a second gate structure 208 located on the second region II, and a third metal layer 203 and a fourth metal layer 204 respectively located on two sides of the second gate structure 208: the second gate structure 208, the third metal layer 203 and the fourth metal layer 204 are parallel to the second direction Y;
a first isolation structure 209 located on the first isolation area B1: the first isolation structure 209 penetrates the first metal layer 201, the second metal layer 202 and the fifth metal layer 205 along the first direction X; and the first gate structure 207 is located on the first isolation structure 209; and
a second isolation structure 210 located on the second isolation area B2: the second isolation structure 210 penetrates the third metal layer 203 and the fourth metal layer 204 along the first direction X, and the second gate structure 208 is located on the second isolation structure 210.

In one embodiment, the first region I also includes a first active area A1 and a second active area A2. The first isolation area B1 is located between the first active area A1 and the second active area A2. The first isolation area B1 is adjacent to the first active area A1 and the second active area A2. The first active area A1, the second active area A2 and the first isolation area B1 are arranged along the second direction Y. The second region II also includes a third active area A3 and a fourth active area A4. The second isolation area B2 is located between the third active area A3 and the fourth active area A4. The second isolation area B2 is adjacent to the third active area A3 and the fourth active area A4. The third active area A3, the fourth active area A4 and the second isolation area B2 are arranged along the second direction Y.

In one embodiment, a conductivity type of a device in the first active area A1 is opposite to a conductivity type of a device in the second active area A2. A conductivity type of a device in the third active area A3 is opposite to a conductivity type of a device in the fourth active area A4.

In one embodiment, the first active area A1 and the third active area A3 are adjacent, and the second active area A2 and the fourth active area A4 are adjacent. The conductivity type of the device in the first active area A1 is same as the conductivity type of the device in the third active area A3, and the conductivity type of the device is N type. The conductivity type of the device in the second active area A2 is same as the conductivity type of the device in the fourth active area A4, and the conductivity type of the device is P type.

In one embodiment, the semiconductor structure also includes a fifth metal layer 205 located on the first region I. The fifth metal layer 205 is located between the second metal layer 202 and the third metal layer 203. The fifth metal layer 205 is parallel to the second direction Y.

In one embodiment, the semiconductor structure also includes: a plurality of dummy gate structures 206 located on the substrate. The plurality of the dummy gate structures 206 is arranged in parallel, and the dummy gate structures 206 is parallel to the second direction Y. The first metal layer 201 is located between the dummy gate structure 206 and the first gate structure 207. The second metal layer 202 is located between the dummy gate structure 206 and the first gate structure 207. The third metal layer 203 is located between the dummy gate structure 206 and the second gate structure 208. The fourth metal layer 204 is located between the dummy gate structure 206 and the second gate structure 208. The fifth metal layer 205 is located between adjacent dummy gate structures 206.

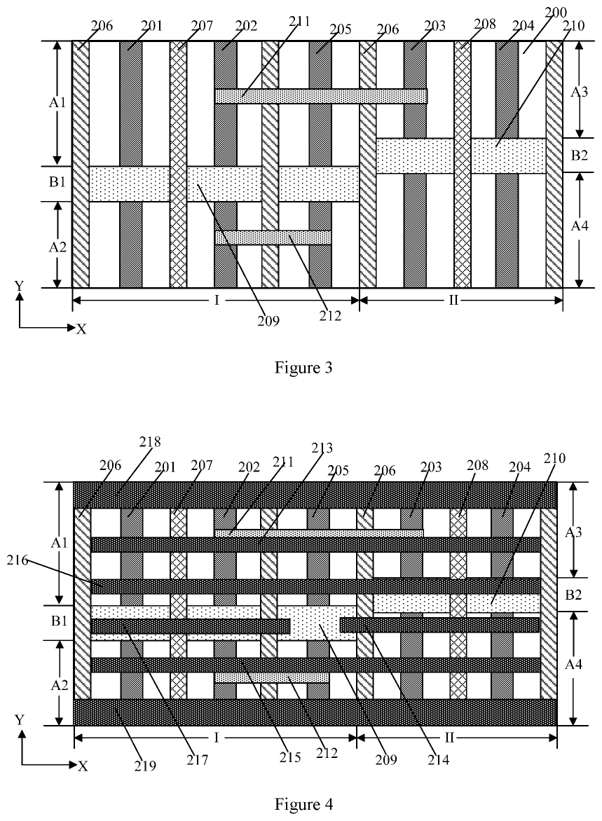

FIGS. 3-5 illustrate schematic diagrams of another process of forming a semiconductor structure consistent with the disclosed embodiments of the present disclosure.

FIG. 3 is a schematic diagram based on FIG. 2. Referring to FIG. 3, the process includes: forming a first connection layer 211 parallel to the first direction X on the substrate 200, where the first connection layer 211 is electrically connected to the second metal layer 202, the fifth metal layer 205 and the third metal layer 203 on the first active area A1 and the third active area A3; and forming a second connection layer 212 parallel to the first direction X on the substrate 200, where the second connection layer 212 is electrically connected to the second metal layer 202 and the fifth metal layer 205 on the second active area A2.

Before forming the first connection layer 211 and the second connection layer 212, the process also includes: forming a second dielectric layer (not shown) on the first dielectric layer. The first connection layer 211 and the second connection layer 212 are located in the second dielectric layer.

The first connection layer 211 is electrically connected to the second metal layer 202, the fifth metal layer 205 and the third metal layer 203 on the first active area A1 and the third active area A3. Accordingly, the second metal layer 202, fifth metal layer 205 and third metal layer 203 may be at a same voltage level. The second connection layer 212 is electrically connected to the second metal layer 202 and the fifth metal layer 205 on the second active area A2. Accordingly, the second metal layer 202 and the fifth metal layer 205 may be at a same voltage level.

Referring to FIG. 4, the process also includes: forming a first conductive layer 213 parallel to the first direction X on the second dielectric layer, where the first conductive layer 213 spans the first active area A1 and the third active area A3, and the first conductive layer 213 is electrically connected to the first metal layer 201 on the first active area A1 and the fourth metal layer 204 on the third active area A3; forming a second conductive layer 214 parallel to the first direction X on the second dielectric layer, where the second conductive layer 214 is electrically connected to the third metal layer 203 on the fourth active area A4, and the second conductive layer 214 is located on the fourth active area A4; and forming a third conductive layer 215 parallel to the first direction X on the second dielectric layer, where the third conductive layer 215 spans the second active area A2 and the fourth active area A4, and the third conductive layer 215 is electrically connected to the first metal layer 201 on the second active area A2 and the fourth metal layer 204 on the fourth active area A4.

Still referring to FIG. 4, the process also includes forming a fourth conductive layer 216 parallel to the first direction X on the second dielectric layer. The fourth conductive layer 216 is electrically connected to the second gate structure 208. The fourth conductive layer 216 spans the first active area A1 and the second isolation area B1.

The first conductive layer 213, the fourth conductive layer 216, the second conductive layer 214 and the third conductive layer 215 are sequentially arranged in parallel with an equal interval.

Still referring to FIG. 4, the process also includes forming a fifth conductive layer 217 parallel to the first direction X on the second dielectric layer. The fifth conductive layer 217 is located on the first isolation area B1. The fifth conductive layer 217 is electrically connected to the first gate structure 207. The central axis of the fifth conductive layer 217 in the first direction X coincides with the central axis of the second conductive layer 214 in the first direction X.

The central axis of the first isolation area B1 in the first direction X does not coincide with the central axis of the second isolation area B2 in the first direction X. As such, when the first conductive layer 213, the fourth conductive layer 216, the second conductive layer 214 and the third conductive layer 215 parallel to the first direction X are formed, under established rules for conductive layer design, a quantity of locations, where the first conductive layer 213, the fourth conductive layer 216, the second conductive layer 214 or the third conductive layer 215 may be electrically connected to the first metal layer 201, the second metal layer 202, the third metal layer 203 and the fourth metal layer 204, the fifth metal layer 205, the first gate structure 207 or the second gate structure 208, may be increased. As a result, a semiconductor structural unit with a small area may be used to form a complex circuit. Accordingly, area may be saved, flexibility of back-end wiring may be increased, and an integration level may be improved.

Still referring to FIG. 4, the process also includes: forming a power supply voltage line 218, electrically connected to the fifth metal layer 205 on the first active area A1, on the second dielectric layer; and forming a ground voltage line 219, electrically connected to the fifth metal layer 205 on the second active area A2, on the second dielectric layer. The power supply voltage line 218 and the ground voltage line 219 are parallel to the first direction X.

In one embodiment, the process also includes: forming a third dielectric layer (not shown) on the second dielectric layer. The first conductive layer 213, the fourth conductive layer 216, the second conductive layer 214, the third conductive layer 215, the fifth conductive layer 217, the power supply voltage line 218 and the ground voltage line 219 are located in the third dielectric layer.

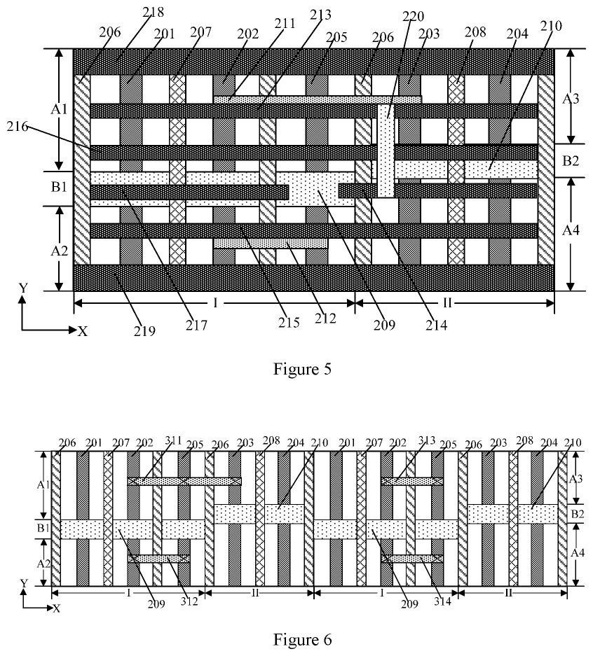

Referring to FIG. 5, the process also includes forming an electrical output layer 220 parallel to the second direction Y on the third dielectric layer. The electrical output layer 220 is electrically connected to the first conductive layer 213 and the second conductive layer 214.

Correspondingly, the present disclosure also provides a semiconductor structure. Referring to FIG. 5, the structure of FIG. 5 is based on the structure of FIG. 2, and also includes:
a first connection layer 211: the first connection layer 211 is electrically connected to the second metal layer 202, the fifth metal layer 205 and the third metal layer 203 on the first active area A1 and the third active area A3;
a second connection layer 212: the second connection layer 212 is electrically connected to the second metal layer 202 and the fifth metal layer 205 on the second active area A2;
a first conductive layer 213 parallel to the first direction X: the first conductive layer 213 spans the first active area A1 and the third active area A3, and the first conductive layer 213 is electrically connected to the first metal layer 201 on the first active area A1 and the fourth metal layer 204 on the third active area A3;
a second conductive layer 214 parallel to the first direction X: the second conductive layer 214 is electrically connected to the third metal layer 203 on the fourth active area A4, and the second conductive layer 214 is located on the fourth active area A4;
a third conductive layer 215 parallel to the first direction X: the third conductive layer 215 spans the second active area A2 and the fourth active area A4, and the third conductive layer 215 is electrically connected to the first metal layer 201 on the second active area A2 and the fourth metal layer 204 on the fourth active area A4;
an electrical output layer 220 parallel to the second direction Y: the electrical output layer 220 is electrically connected to the first conductive layer 213 and the second conductive layer 214; and
a fourth conductive layer 216 parallel to the first direction X: the fourth conductive layer 216 is electrically connected to the second gate structure 208, and the fourth conductive layer 216 spans the first active area A1 and the second isolation area B1.

The first conductive layer 213, the fourth conductive layer 216, the second conductive layer 214 and the third conductive layer 215 are sequentially arranged in parallel with an equal interval.

The structure also includes a fifth conductive layer 217 parallel to the first direction X. The fifth conductive layer 217 is located on the first isolation area B1. The fifth conductive layer 217 is electrically connected to the first gate structure 207. The central axis of the fifth conductive layer 217 in the first direction X coincides with the central axis of the second conductive layer 214 in the first direction X.

The structure also includes a power supply voltage line 218 electrically connected to the fifth metal layer 205 on the first active area A1, and a ground voltage line 219 electrically connected to the fifth metal layer 205 on the second active area A2. The power supply voltage line 218 and the ground voltage line 219 are parallel to the first direction X.

FIGS. 6-8 illustrate schematic diagrams of another process of forming a semiconductor structure consistent with the disclosed embodiments of the present disclosure.

FIG. 6 is a schematic structural diagram based on FIG. 2. Referring to FIG. 6, a plurality of unit areas includes a first unit area and a second unit area. Units of the first unit area and the second unit area are arranged along the first direction X. The second region II of the first unit area is adjacent to the first region I of the second unit area. The first active area A1 of the second unit area is adjacent to the third active area A3 of the first unit area. The second active area A2 of the second unit area is adjacent to the fourth active area A4 of the first unit area.

Still referring to FIG. 6, the process includes: forming a first connection layer 311 parallel to the first direction X on the first dielectric layer, where the first connection layer 311 is electrically connected to the second metal layer 202, the fifth metal layer 205 and the third metal layer 203 on the first active area A1 and the third active area A3 of the first unit area; forming a second connection layer 312 parallel to the first direction X on the first dielectric layer, where the second connection layer 312 is electrically connected to the second metal layer 202 and the fifth metal layer 205 on the second active area A2 of the first unit area; forming a third connection layer 313 parallel to the first direction X on the first dielectric layer, where the central axis of the third connection layer 313 in the first direction X coincides with the central axis of the first connection layer 311 in the first direction X, and the third connection layer 313 is electrically connected to the second metal layer 202 and the fifth metal layer 205 on the first active area A1 of the second unit area; forming a fourth connection layer 314 parallel to the first direction X on the first dielectric layer, where the central axis of the fourth connection layer 314 in the first direction X coincides with the central axis of the second connection layer 312 in the first direction X, and the fourth connection layer 314 is electrically connected to the second metal layer 202 and the fifth metal layer 205 on the second active area A2 of the second unit area.

The first connection layer 311, the second connection layer 312, the third connection layer 313 and the fourth connection layer 314 may be formed simultaneously.

The first connection layer 311 is configured to keep the second metal layer 202, the fifth metal layer 205 and the third metal layer 203 on the first active area A1 and the third active area A3 at a same voltage level. The second connection layer 312 is configured to make the second metal layer 202 and the fifth metal layer 205 on the second active area A2 of the first unit area at a same voltage level. The third connection layer 313 is configured to keep the second metal layer 202 and the fifth metal layer 205 on the first active area A1 of the second unit area at a same voltage level. The fourth connection layer 314 is configured to keep the second metal layer 202 and the fifth metal layer 205 on the second active area A2 of the second unit area at a same voltage level.

In one embodiment, the process also includes: forming a second dielectric layer (not shown) on the first dielectric layer. The first connection layer 311, the second connection layer 312, the third connection layer 313 and the fourth connection layer 314 are located in the second dielectric layer.

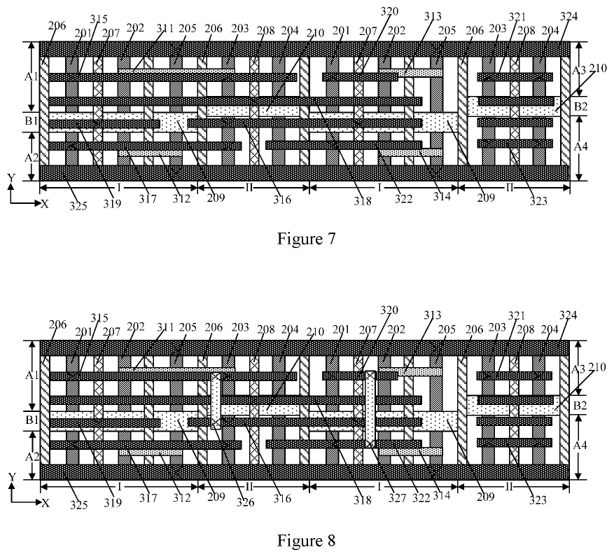

Referring to FIG. 7, the process also includes forming a first conductive layer 315 located on the first unit area on the second dielectric layer. The first conductive layer 315 is parallel to the first direction X. The first conductive layer 315 spans the first active area A1 and the third active area A3 of the first unit area. The first conductive layer 315 is electrically connected to the first metal layer 201 on the first active area A1 of the first unit area and the fourth metal layer 204 on the third active area A3.

The process also includes forming a second conductive layer 316 located on the fourth active area A4 of the first unit area and the first isolation area B1 of the second unit area on the second dielectric layer. The second conductive layer 316 is parallel to the first direction X. The second conductive layer 316 is electrically connected to the fourth metal layer 204 on the fourth active area A4 of the first unit area and the first gate structure 207 of the second unit area.

The process also includes forming a third conductive layer 317 located on the first unit area on the second dielectric layer. The third conductive layer 317 is parallel to the first direction X. The third conductive layer 317 spans the second active area A2 and the fourth active area A4 of the first unit area. The third conductive layer 317 is electrically connected to the first metal layer 201 on the second active area A2 of the first unit area and the third metal layer 203 on the fourth active area A4.

The process also includes forming a fourth conductive layer 318 located on the first unit area on the second dielectric layer. The fourth conductive layer 318 is parallel to the first direction X. The fourth conductive layer 318 is electrically connected to the second gate structure 208 of the first unit area. The fourth conductive layer 318 spans the first active area A1 and the second isolation area B2 of the first unit area.

The process also includes forming a fifth conductive layer 319 located on the first unit area on the second dielectric layer. The fifth conductive layer 319 is parallel to the first direction X. The fifth conductive layer 319 is located on the first isolation area B1. The fifth conductive layer 319 is electrically connected to the first gate structure 207 of the first unit area. The central axis of the fifth conductive layer 319 in the first direction X coincides with the central axis of the second conductive layer 316 in the first direction X.

In one embodiment, the first conductive layer 315, the fourth conductive layer 318, the second conductive layer 316 and the third conductive layer 317 are sequentially arranged in parallel with an equal interval.

The central axis of the first isolation area B1 of the first unit area in the first direction X does not coincide with the central axis of the second isolation area B2 in the first direction X. The central axis of the first isolation area B1 of the second unit area in the first direction X does not coincide with the central axis of the second isolation area B2 in the first direction X. Accordingly, when forming the first conductive layer 315, the fourth conductive layer 318, the second conductive layer 316 and the third conductive layer 317 parallel to the first direction X, under established rules for conductive layer design, a quantity of locations, where the conductive layer may be electrically connected to the first metal layer 201, the second metal layer 202, the third metal layer 203, the fourth metal layer 204, the first gate structure 207 or the second gate structure 208, may increase. As such, two semiconductor structural unit areas with small areas may be used to form a complex circuit. Accordingly, area may be saved, flexibility of back-end wiring may be increased, and an integration level may be improved.

Still referring to FIG. 7, the process also includes: forming a sixth conductive layer 320 located on the first active area A1 of the second unit area on the second dielectric layer. The sixth conductive layer 320 is parallel to the first direction X. The sixth conductive layer 320 is electrically connected to the first metal layer 201 on the first active area A1 of the second unit area.

The process also includes forming a seventh conductive layer 321 located on the third active area A3 of the second unit area on the second dielectric layer. The seventh conductive layer 321 is parallel to the first direction X. The seventh conductive layer 321 is connected to the third metal layer 203 and the fourth metal layer 204 on the third active area A3 of the second unit area.

The process also includes forming an eighth conductive layer 322 located on the second active area A2 of the second unit area on the second dielectric layer. The eighth conductive layer 322 is parallel to the first direction X. The eighth conductive layer 322 is electrically connected to the first metal layer 201 on the second active area A2 of the second unit area.

The process also includes forming a ninth conductive layer 323 located on the fourth active area A4 of the second unit area on the second dielectric layer. The ninth conductive layer 323 is parallel to the first direction X. The ninth conductive layer 323 is electrically connected to the third metal layer 203 and the fourth metal layer 204 on the fourth active area A4 of the second unit area.

In one embodiment, the central axes of the first conductive layer 315, the sixth conductive layer 320 and the seventh conductive layer 321 in the first direction X coincide with each other. The central axes of the third conductive layer 317, the eighth conductive layer 322, and the ninth conductive layer 323 in the first direction X coincide with each other.

The first conductive layer 315, the fourth conductive layer 318, the second conductive layer 316, the third conductive layer 317, the fifth conductive layer 319, the sixth conductive layer 320, the seventh conductive layer 321, the eighth conductive layer 322 and the ninth conductive layer 323 may be formed simultaneously. In one embodiment, the process also includes forming a third dielectric layer (not shown) on the second dielectric layer. The first conductive layer 315, the fourth conductive layer 318, the second conductive layer 316, the third conductive layer 317, the fifth conductive layer 319, the sixth conductive layer 320, the seventh conductive layer 321, the eighth conductive layer 322 and the ninth conductive layer 323 are located in the third dielectric layer.

Still referring to FIG. 7, the process also includes: forming a power supply voltage line 324, electrically connected to the fifth metal layer 205 on the first active area A1 of the first unit area and the fifth metal layer 205 on the first active area A1 of the second unit area, in the third dielectric layer; and forming a ground voltage line 325, electrically connected to the fifth metal layer 205 on the second active area A2 of the first unit area and the fifth metal layer 205 on the second active area A2 of the second unit area, in the third dielectric layer. The power supply voltage line 324 and the ground voltage line 325 are parallel to the first direction.

Referring to FIG. 8, the process also includes: forming a first electrical output layer 326 parallel to the second direction Y on the third dielectric layer, where the first electrical output layer 326 is electrically connected to the first conductive layer 315 and the second conductive layer 316 on the first unit area; and forming a second electrical output layer 327 parallel to the second direction Y on the third dielectric layer, where the second electrical output layer 327 is electrically connected to the sixth conductive layer 320 and the eighth conductive layer 322 on the second unit area.

Correspondingly, the present disclosure also provides a semiconductor structure. Referring to FIG. 8, the semiconductor structure of FIG. 8 is based on the structure of FIG. 2.

In one embodiment, referring to FIG. 8, the semiconductor structure includes a plurality of unit areas. The plurality of unit areas includes a first unit area and a second unit area. Units of the first unit area and the second unit area are arranged along the first direction X. The second region II of the first unit area is adjacent to the first region I of the second unit area. The first active area A1 of the second unit area is adjacent to the third active area A3 of the first unit area. The second active area A2 of the second unit area is adjacent to the fourth active area A4 of the first unit area.

In one embodiment, referring to FIG. 8, the semiconductor structure also includes: a first connection layer 311 parallel to the first direction X, where the first connection layer 311 is electrically connected to the second metal layer 202, the fifth metal layer 205 and the third metal layer 203 on the first active area A1 and the third active area A3 of the first unit area; a second connection layer 312 parallel to the first direction X, where the second connection layer 312 is electrically connected to the second metal layer 202 and the fifth metal layer 205 on the second active area A2 of the first unit area; a third connection layer 313 parallel to the first direction X, where the central axis of the third connection layer 313 in the first direction X coincides with the central axis of the first connection layer 311 in the first direction X, and the third connection layer 313 is electrically connected to the second metal layer 202 and the fifth metal layer 205 on the first active area A1 of the second unit area; and a fourth connection layer 314 parallel to the first direction X, where the central axis of the fourth connection layer 314 in the first direction X coincides with the central axis of the second connection layer 312 in the first direction X, and the fourth connection layer 314 is electrically connected to the second metal layer 202 and the fifth metal layer 205 on the second active area A2 of the second unit area.

In one embodiment, referring to FIG. 8, the semiconductor structure also includes: a first conductive layer 315 located on the first unit area, where the first conductive layer 315 is parallel to the first direction X, the first conductive layer 315 spans the first active area A1 and the third active area A3 of the first unit area, and the first conductive layer 315 is electrically connected to the first metal layer 201 on the first active area A1 of the first unit area and the fourth metal layer 204 on the third active area A3; a second conductive layer 316 located on the fourth active area A4 of the first unit area and the first isolation area B1 of the second unit area, where the second conductive layer 316 is parallel to the first direction X, and the second conductive layer 316 is electrically connected to the fourth metal layer 204 on the fourth active area A4 of the first unit area and the first gate structure 207 of the second unit area; a third conductive layer 317 located on the first unit area, where the third conductive layer 317 is parallel to the first direction X, the third conductive layer 317 spans the second active area A2 and the fourth active area A4 of the first unit area, and the third conductive layer 317 is electrically connected to the first metal layer 201 on the second active area A2 of the first unit area and the third metal layer 203 on the fourth active area A4; a fourth conductive layer 318 located on the first unit area, where the fourth conductive layer 318 is parallel to the first direction X, the fourth conductive layer 318 is electrically connected to the second gate structure 208 of the first unit area, and the fourth conductive layer 318 spans the first active area A1 and the second isolation area B2 of the first unit area; and a fifth conductive layer 319 located on the first unit area, where the fifth conductive layer 319 is parallel to the first direction X, the fifth conductive layer 319 is located on the first isolation area B1, the fifth conductive layer 319 is electrically connected to the first gate structure 207 of the first unit area, and the central axis of the fifth conductive layer 319 in the first direction X coincides with the central axis of the second conductive layer 316 in the first direction X.

In one embodiment, the first conductive layer 315, the fourth conductive layer 318, the second conductive layer 316 and the third conductive layer 317 are sequentially arranged in parallel with an equal interval.

In one embodiment, referring to FIG. 8, the semiconductor structure also includes: a sixth conductive layer 320 located on the first active area A1 of the second unit area, where the sixth conductive layer 320 is parallel to the first direction X, and the sixth conductive layer 320 is electrically connected to the first metal layer 201 on the first active area A1 of the second unit area; a seventh conductive layer 321 located on the third active area A3 of the second unit area, where the seventh conductive layer 321 is parallel to the first direction X, and the seventh conductive layer 321 is connected to the third metal layer 203 and the fourth metal layer 204 on the third active area A3 of the second unit area; an eighth conductive layer 322 located on the second active area A2 of the second unit area, where the eighth conductive layer 322 is parallel to the first direction X, and the eighth conductive layer 322 is electrically connected to the first metal layer 201 on the second active area A2 of the second unit area; and a ninth conductive layer 323 located on the fourth active area A4 of the second unit area, where the ninth conductive layer 323 is parallel to the first direction X, and the ninth conductive layer 323 is electrically connected to the third metal layer 203 and the fourth metal layer 204 on the fourth active area A4 of the second unit area.

In one embodiment, the central axes of the first conductive layer 315, the sixth conductive layer 320 and the seventh conductive layer 321 in the first direction X coincide with each other. The central axes of the third conductive layer 317, the eighth conductive layer 322, and the ninth conductive layer 323 in the first direction X coincide with each other.

In one embodiment, referring to FIG. 8, the semiconductor structure also includes: a power supply voltage line 324 electrically connected to the fifth metal layer 205 on the first active area A1 of the first unit area and the fifth metal layer 205 on the first active area A1 of the second unit area; and a ground voltage line 325 electrically connected to the fifth metal layer 205 on the second active area A2 of the first unit area and the fifth metal layer 205 on the second active area A2 of the second unit area. The power supply voltage line 324 and the ground voltage line 325 each are parallel to the first direction.

In one embodiment, referring to FIG. 8, the semiconductor structure also includes: a first electrical output layer 326 parallel to the second direction Y, where the first electrical output layer 326 is electrically connected to the first conductive layer 315 and the second conductive layer 316 on the first unit area; and a second electrical output layer 327 parallel to the second direction Y, where the second electrical output layer 327 is electrically connected to the sixth conductive layer 320 and the eighth conductive layer 322 on the second unit area.

FIG. 9 illustrates a schematic diagram of another process of forming a semiconductor structure consistent with the disclosed embodiments of the present disclosure.

FIG. 9 is a schematic structural diagram based on FIG. 2. Referring to FIG. 9, the semiconductor structure includes a plurality of unit areas. The plurality of unit areas includes a first unit area, a second unit area, a third unit area and a fourth unit area.

The first unit area and the second unit area are arranged along the first direction X parallel to the surface of the substrate 200, and a second region II of the first unit area is adjacent to a first region I of the second unit area. The third unit area and the fourth unit area are arranged along the first direction X parallel to the surface of the substrate 200. A second region II of the third unit area is adjacent to a first region I of the fourth unit area. The first unit area and the fourth unit area are arranged along a second direction Y parallel to the substrate surface, and the first region I of the first unit area is adjacent to the second region II of the fourth unit area. The second region II of the first unit area is adjacent to the first region I of the fourth unit area. The second unit area and the third unit area are arranged along the second direction Y parallel to the surface of the substrate 200. The second region II of the second unit area is adjacent to the first region I of the third unit area, and the first region I of the second unit area is adjacent to the second region II of the third unit area.

The central axis of the first isolation area B1 in the first direction X does not coincide with the central axis of the second isolation area B2 in the first direction X. Accordingly, when a conductive layer parallel to the first direction X is subsequently formed, under established rules for conductive layer design, a quantity of locations, where the conductive layer may be electrically connected to the first metal layer 201, the second metal layer 202, the third metal layer 203, the fourth metal layer 204, the first gate structure 207 or the second gate structure 208, may increase. As a result, four or a plurality of semiconductor structural unit areas with small areas may be used to form a complex circuit. Accordingly, area may be saved, flexibility of back-end wiring may be increased, and an integration level may be improved.

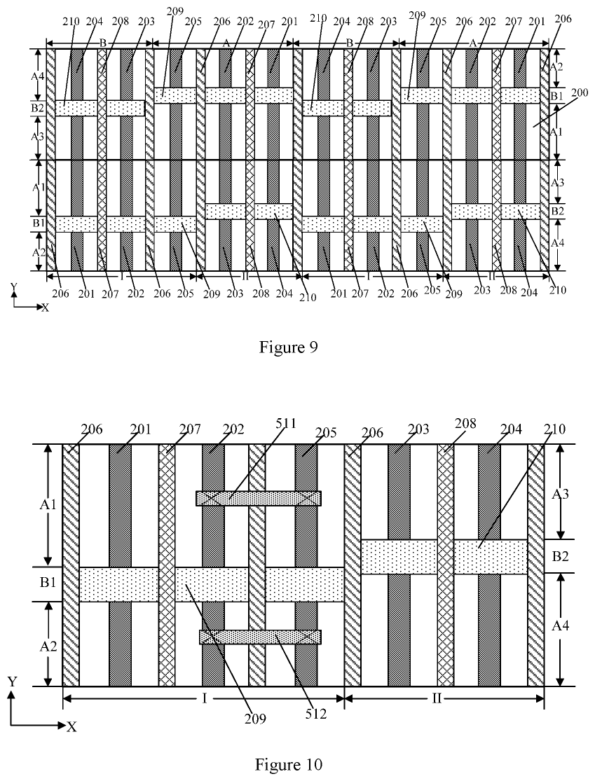

FIGS. 10-12 illustrate schematic diagrams of another process of forming a semiconductor structure consistent with the disclosed embodiments of the present disclosure.

FIG. 10 is a schematic structural diagram based on FIG. 2. Referring to FIG. 10, the process includes: forming a first connection layer 511 parallel to the first direction X on the first dielectric layer, where the first connection layer 511 is electrically connected to the second metal layer 202 and the fifth metal layer 205 on the first active area A1; and forming a second connection layer 512 parallel to the first direction X on the first dielectric layer, where the second connection layer 512 is electrically connected to the second metal layer 202 and the fifth metal layer 205 on the second active area A2.

In one embodiment, the process also includes: forming a second dielectric layer (not shown) on the first dielectric layer, where the first connection layer 511 and the second connection layer 512 are located in the second dielectric layer.

The first connection layer 511 is configured to keep the second metal layer 202 and the fifth metal layer 205 on the first active area A1 at a same voltage level. The second connection layer 512 is configured to keep the second metal layer 202 and the fifth metal layer 205 on the second active area A2 at a same voltage level.

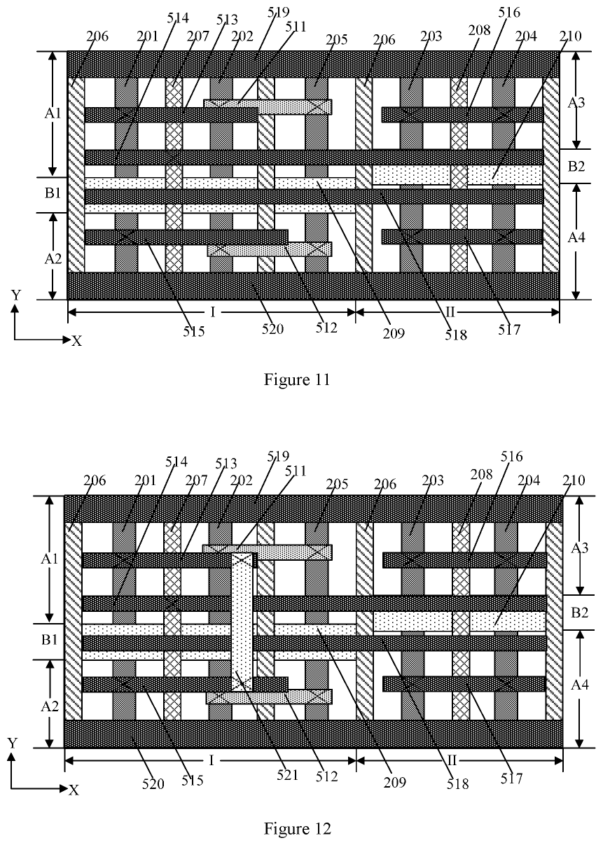

Referring to FIG. 11, the process also includes: forming a first conductive layer 513 parallel to the first direction X on the second dielectric layer, where the first conductive layer 513 is electrically connected to the first metal layer 201 on the first active area A1; forming a second conductive layer 514 parallel to the first direction X on the second dielectric layer, where the second conductive layer 514 is electrically connected to the first gate structure 207, and the second conductive layer 514 spans the first active area A1 and the second isolation area B2; and forming a third conductive layer 515 parallel to the first direction X on the second dielectric layer, where the third conductive layer 515 is electrically connected to the first metal layer 201 on the second active area A2.

The first region I includes a first isolation area B1 and the second region II includes a second isolation area B2. The central axis of the first isolation area B1 in the first direction X does not coincide with the central axis of the second isolation area B2 in the first direction X. Accordingly, the second conductive layer 514 may form an active gate contact electrically connected to the first gate structure 207 on the first active area A1. As such, area may be saved, and wiring flexibility may be increased.

Still referring to FIG. 11, the process also includes: forming a fourth conductive layer 516 parallel to the first direction X on the second dielectric layer, where the fourth conductive layer 516 is electrically connected to the third metal layer 203 and the fourth metal layer 204 on the third active area A3, and the central axis of the fourth conductive layer 516 in the first direction X coincides with the central axis of the first conductive layer 513 in the first direction X; forming a fifth conductive layer 517 parallel to the first direction X on the second dielectric layer, where the fifth conductive layer 517 is electrically connected to the third metal layer 203 and the fourth metal layer 204 on the fourth active area A4, and the central axis of the fifth conductive layer 517 in the first direction X coincides with the central axis of the third conductive layer 515 in the first direction X; and forming a sixth conductive layer 518 parallel to the first direction X on the second dielectric layer, where the sixth conductive layer 518 spans the first isolation area B1 and the fourth active area A4.

The fourth conductive layer 516 is electrically connected to the third metal layer 203 and the fourth metal layer 204 on the third active area A3, and is configured to make the second gate structure 208 on the third active area A3 invalid. The fifth conductive layer 517 is electrically connected to the third metal layer 203 and the fourth metal layer 204 on the fourth active area A4, and is configured to make the second gate structure 208 on the fourth active area A4 invalid.

In one embodiment, the first conductive layer 513, the second conductive layer 514, the sixth conductive layer 518 and the third conductive layer 515 are sequentially arranged in parallel with an equal interval.

Still referring to FIG. 11, the process also includes: forming a power supply voltage line 519 parallel to the first direction X on the second dielectric layer, where the power supply voltage line 519 is electrically connected to the fifth metal layer 205 on the first active area A1; and forming a ground voltage line 520 parallel to the first direction X on the second dielectric layer, where the ground voltage line 520 is electrically connected to the fifth metal layer 205 on the second active area A2.

In one embodiment, the process also includes forming a third dielectric layer (not shown) on the second dielectric layer. The first conductive layer 513, the second conductive layer 514, the sixth conductive layer 518, the third conductive layer 515, the fourth conductive layer 516, the fifth conductive layer 517, the power supply voltage line 519 and the ground voltage line 520 are located within the third dielectric layer.

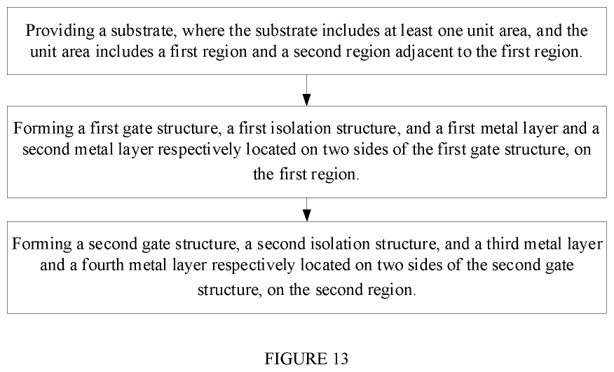

Referring to FIG. 12, the process also includes forming an electrical output layer 521 parallel to the second direction Y on the third dielectric layer. The electrical output layer 521 is electrically connected to the first conductive layer 513 and the third conductive layer 515.

Correspondingly, the present disclosure also provides a semiconductor structure. Still referring to FIG. 12, based on the structure of FIG. 2, the structure also includes:
a first connection layer 511 parallel to the first direction X, where the first connection layer 511 is electrically connected to the second metal layer 202 and the fifth metal layer 205 on the first active area A1;
a second connection layer 512 parallel to the first direction X, where the second connection layer 512 is electrically connected to the second metal layer 202 and the fifth metal layer 205 on the second active area A2;
a first conductive layer 513 parallel to the first direction X, where the first conductive layer 513 is electrically connected to the first metal layer 201 on the first active area A1;
a second conductive layer 514 parallel to the first direction X, where the second conductive layer 514 is electrically connected to the first gate structure 207, and the second conductive layer 514 spans the first active area A1 and the second isolation area B2;
a third conductive layer 515 parallel to the first direction X, where the third conductive layer 515 is electrically connected to the first metal layer 201 on the second active area A2;
a fourth conductive layer 516 parallel to the first direction X, where the fourth conductive layer 516 is electrically connected to the third metal layer 203 and the fourth metal layer 204 on the third active area A3, and the central axis of the fourth conductive layer 516 in the first direction X coincides with the central axis of the first conductive layer 513 in the first direction X;
a fifth conductive layer 517 parallel to the first direction X, where the fifth conductive layer 517 is electrically connected to the third metal layer 203 and the fourth metal layer 204 on the fourth active area A4, and the central axis of the fifth conductive layer 517 in the first direction X coincides with the central axis of the third conductive layer 515 in the first direction X;
a sixth conductive layer 518 parallel to the first direction X, where the sixth conductive layer 518 spans the first isolation area B1 and the fourth active area A4;
a power supply voltage line 519 parallel to the first direction X, where the power supply voltage line 519 is electrically connected to the fifth metal layer 205 on the first active area A1;
a ground voltage line 520 parallel to the first direction X, where the ground voltage line 520 is electrically connected to the fifth metal layer 205 on the second active area A2; and
an electrical output layer 521 parallel to the second direction Y, where the electrical output layer 521 is electrically connected to the first conductive layer 513 and the third conductive layer 515.

1. A semiconductor structure, comprising:
a substrate, wherein the substrate includes at least one unit area, a unit area of the at least one unit area includes a first region and a second region adjacent to the first region, the first region and the second region are arranged along a first direction, the first region includes a first active area, a first isolation area, and a second active area arranged along a second direction, the first active area and the second active area are located on two sides of the first isolation area, the second region includes a third active area, a second isolation area, and a fourth active area arranged along the second direction, the third active area and a fourth active area are located on two sides of the second isolation area, and a central axis of the first isolation area parallel to the first direction does not coincide with a central axis of the second isolation area parallel to the first direction, the first direction is parallel to a surface of the substrate, and the first direction and the second direction are perpendicular to each other;
a first gate structure located on the first region, wherein the first gate structure spans the first active area, the first isolation area and the second active area; and a first metal layer and a second metal layer respectively located on two sides of the first gate structure, wherein the first gate structure, the first metal layer, and the second metal layer are parallel to the second direction;
a second gate structure located on the second region, wherein the second gate structure spans the third active area, the second isolation area and the fourth active area; and a third metal layer and a fourth metal layer respectively located on two sides of the second gate structure, wherein the second gate structure, the third metal layer and the fourth metal layer are parallel to the second direction;
a first isolation structure located on the first isolation area, wherein the first isolation structure penetrates the first metal layer and the second metal layer along the first direction, and the first gate structure is located over the first isolation structure; and
a second isolation structure located on the second isolation area, wherein the second isolation structure penetrates the third metal layer and the fourth metal layer along the first direction, and the second gate structure is located over the second isolation structure.

2. The semiconductor structure according to claim 1, wherein:
the first isolation area is adjacent to the first active area and the second active area; and the second isolation area is adjacent to the third active area and the fourth active area.

3. The semiconductor structure according to claim 2, wherein:
a conductivity type of a device in the first active area is opposite to a conductivity type of a device in the second active area, and a conductivity type of a device in the third active area is opposite to a conductivity type of a device in the fourth active area.

4. The semiconductor structure according to claim 3, wherein:
the first active area and the third active area are adjacent, and the second active area and the fourth active area are adjacent; the conductivity type of the device in the first active area is same as the conductivity type of the device in the third active area, and the conductivity type of the device is N type; the conductivity type of the device in the second active area is same as the conductivity type of the device in the fourth active area, and the conductivity type of the device is P type.

5. (canceled)

6. The semiconductor structure according to claim 2, further comprising:
a fifth metal layer located on the first region, wherein the fifth metal layer is located between the second metal layer and the third metal layer, the fifth metal layer is parallel to the second direction, and the first isolation structure also penetrates the fifth metal layer along the first direction; and
a plurality of dummy gate structures located over the substrate, wherein the plurality of the dummy gate structures is arranged in parallel, the plurality of dummy gate structures is parallel to the second direction, the first metal layer is located between a dummy gate structure of the plurality of the dummy gate structures and the first gate structure, the second metal layer is located between the dummy gate structure and the first gate structure, the third metal layer is located between the dummy gate structure and the second gate structure, the fourth metal layer is located between the dummy gate structure and the second gate structure, and the fifth metal layer is located between adjacent dummy gate structures of the plurality of the dummy gate structures.

7. The semiconductor structure according to claim 6, further comprising:
a first connection layer parallel to the first direction, wherein the first connection layer is electrically connected to the second metal layer, and the fifth metal layer and the third metal layer on the first active area and the third active area; a second connection layer parallel to the first direction, wherein the second connection layer is electrically connected to the second metal layer and the fifth metal layer on the second active area; a first conductive layer parallel to the first direction, wherein the first conductive layer spans the first active area and the third active area, and the first conductive layer is electrically connected to the first metal layer on the first active area and the fourth metal layer on the third active area; a second conductive layer parallel to the first direction, wherein the second conductive layer is electrically connected to the third metal layer on the fourth active area, and the second conductive layer is located on the fourth active area; a third conductive layer parallel to the first direction, wherein the third conductive layer spans the second active area and the fourth active area, and the third conductive layer is electrically connected to the first metal layer on the second active area and the fourth metal layer on the fourth active area; and an electrical output layer parallel to the second direction, wherein the electrical output layer is electrically connected to the first conductive layer and the second conductive layer.

8. The semiconductor structure according to claim 7, further comprising:
a fourth conductive layer parallel to the first direction, wherein the fourth conductive layer is electrically connected to the second gate structure, and the fourth conductive layer spans the first active area and the second isolation area.

9. The semiconductor structure according to claim 8, wherein:
the first conductive layer, the fourth conductive layer, the second conductive layer and the third conductive layer are sequentially arranged in parallel with an equal interval.

10. The semiconductor structure according to claim 8, further comprising:
a fifth conductive layer parallel to the first direction, wherein the fifth conductive layer is located on the first isolation area, the fifth conductive layer is electrically connected to the first gate structure, a central axis of the fifth conductive layer in the first direction coincides with a central axis of the second conductive layer in the first direction.

11. The semiconductor structure according to claim 7, further comprising:
a power supply voltage line electrically connected to the fifth metal layer on the first active area; and a ground voltage line electrically connected to the fifth metal layer on the second active area, wherein the power supply voltage line and the ground voltage line are parallel to the first direction.

12. The semiconductor structure according to claim 6, further comprising a plurality of unit areas, wherein:
the plurality of unit areas includes a first unit area and a second unit area, units of the first unit area and the second unit area are arranged along the first direction, the second region of the first unit area is adjacent to the first region of the second unit area, the first active area of the second unit area is adjacent to the third active area of the first unit area, and the second active area of the second unit area is adjacent to the fourth active area of the first unit area.

13. The semiconductor structure according to claim 12, further comprising:
a first connection layer parallel to the first direction, wherein the first connection layer is electrically connected to the second metal layer, the fifth metal layer and the third metal layer on the first active area and the third active area of the first unit area; a second connection layer parallel to the first direction, wherein the second connection layer is electrically connected to the second metal layer and the fifth metal layer on the second active area of the first unit area; a third connection layer parallel to the first direction, wherein a central axis of the third connection layer in the first direction coincides with a central axis of the first connection layer in the first direction, and the third connection layer is electrically connected to the second metal layer and the fifth metal layer on the first active area of the second unit area; and a fourth connection layer parallel to the first direction, wherein a central axis of the fourth connection layer in the first direction coincides with a central axis of the second connection layer in the first direction, and the fourth connection layer is electrically connected to the second metal layer and the fifth metal layer on the second active area of the second unit area.

14. The semiconductor structure according to claim 13, further comprising:
a first conductive layer located on the first unit area, wherein the first conductive layer is parallel to the first direction, the first conductive layer spans the first active area and the third active area of the first unit area, and the first conductive layer is electrically connected to the first metal layer on the first active area of the first unit area and the fourth metal layer on the third active area; a second conductive layer located on the fourth active area of the first unit area and the first isolation area of the second unit area, wherein the second conductive layer is parallel to the first direction, and the second conductive layer is electrically connected to the fourth metal layer on the fourth active area of the first unit area and the first gate structure of the second unit area; a third conductive layer located on the first unit area, wherein the third conductive layer is parallel to the first direction, the third conductive layer spans the second active area and the fourth active area of the first unit area, and the third conductive layer is electrically connected to the first metal layer on the second active area of the first unit area and the third metal layer on the fourth active area; a fourth conductive layer located on the first unit area, wherein the fourth conductive layer is parallel to the first direction, the fourth conductive layer is electrically connected to the second gate structure of the first unit area, and the fourth conductive layer spans the first active area and the second isolation area of the first unit area; and a fifth conductive layer located on the first unit area, wherein the fifth conductive layer is parallel to the first direction, the fifth conductive layer is located on the first isolation area, the fifth conductive layer is electrically connected to the first gate structure of the first unit area, and a central axis of the fifth conductive layer in the first direction coincides with a central axis of the second conductive layer in the first direction.

15. The semiconductor structure according to claim 14, wherein:
the first conductive layer, the fourth conductive layer, the second conductive layer and the third conductive layer are sequentially arranged in parallel with an equal interval.

16. The semiconductor structure according to claim 14, further comprising:
a sixth conductive layer located on the first active area of the second unit area, wherein the sixth conductive layer is parallel to the first direction, and the sixth conductive layer is electrically connected to the first metal layer on the first active area of the second unit area; a seventh conductive layer located on the third active area of the second unit area, wherein the seventh conductive layer is parallel to the first direction, and the seventh conductive layer is connected to the third metal layer and the fourth metal layer on the third active area of the second unit area; an eighth conductive layer located on the second active area of the second unit area, wherein the eighth conductive layer is parallel to the first direction, and the eighth conductive layer is electrically connected to the first metal layer on the second active area of the second unit area; and a ninth conductive layer located on the fourth active area of the second unit area, wherein the ninth conductive layer is parallel to the first direction, the ninth conductive layer is electrically connected to the third metal layer and the fourth metal layer on the fourth active area of the second unit area, central axes of the first conductive layer, the sixth conductive layer and the seventh conductive layer in the first direction coincide with each other, and central axes of the third conductive layer, the eighth conductive layer, and the ninth conductive layer in the first direction coincide with each other.

17. The semiconductor structure according to claim 16, further comprising:
a first electrical output layer parallel to the second direction, wherein the first electrical output layer is electrically connected to the first conductive layer and the second conductive layer on the first unit area; and a second electrical output layer parallel to the second direction, wherein the second electrical output layer is electrically connected to the sixth conductive layer and the eighth conductive layer on the second unit area; and
a power supply voltage line electrically connected to the fifth metal layer on the first active area of the first unit area and the fifth metal layer on the first active area of the second unit area; and a ground voltage line electrically connected to the fifth metal layer on the second active area of the first unit area and the fifth metal layer on the second active area of the second unit area, wherein the power supply voltage line and the ground voltage line each are parallel to the first direction.

18. (canceled)

19. The semiconductor structure according to claim 6, further comprising a plurality of unit areas, wherein:
the plurality of unit areas includes a first unit area, a second unit area, a third unit area and a fourth unit area; the first unit area and the second unit area are arranged along the first direction parallel to the surface of the substrate, and a second region of the first unit area is adjacent to a first region of the second unit area; the third unit area and the fourth unit area are arranged along the first direction parallel to the surface of the substrate, and a second region of the third unit area is adjacent to a first region of the fourth unit area; the first unit area and the fourth unit area are arranged along the second direction parallel to the substrate surface, and the first region of the first unit area is adjacent to the second region of the fourth unit area, and the second region of the first unit area is adjacent to the first region of the fourth unit area; and the second unit area and the third unit area are arranged along the second direction parallel to the surface of the substrate, the second region of the second unit area is adjacent to the first region of the third unit area, and the first region of the second unit area is adjacent to the second region of the third unit area.

20. The semiconductor structure according to claim 6, further comprising:
a first connection layer parallel to the first direction, wherein the first connection layer is electrically connected to the second metal layer and the fifth metal layer on the first active area; a second connection layer parallel to the first direction, wherein the second connection layer is electrically connected to the second metal layer and the fifth metal layer on the second active area; a first conductive layer parallel to the first direction, wherein the first conductive layer is electrically connected to the first metal layer on the first active area; a second conductive layer parallel to the first direction, wherein the second conductive layer is electrically connected to the first gate structure, and the second conductive layer spans the first active area and the second isolation area; a third conductive layer parallel to the first direction, wherein the third conductive layer electrically connected to the first metal layer on the second active area; and an electrical output layer parallel to the second direction, wherein the electrical output layer is electrically connected to the first conductive layer and the third conductive layer.

21. The semiconductor structure according to claim 20, further comprising:
a fourth conductive layer parallel to the first direction, wherein the fourth conductive layer is electrically connected to the third metal layer and the fourth metal layer on the third active area, and a central axis of the fourth conductive layer in the first direction X coincides with a central axis of the first conductive layer in the first direction; and a fifth conductive layer parallel to the first direction, wherein the fifth conductive layer is electrically connected to the third metal layer and the fourth metal layer on the fourth active area, and a central axis of the fifth conductive layer in the first direction coincides with a central axis of the third conductive layer in the first direction; and
a sixth conductive layer parallel to the first direction, wherein the sixth conductive layer spans the first isolation area and the fourth active area, and the first conductive layer, the second conductive layer, the sixth conductive layer and the third conductive layer are sequentially arranged in parallel with an equal interval; a power supply voltage line parallel to the first direction, wherein the power supply voltage line is electrically connected to the fifth metal layer on the first active area; and a ground voltage line parallel to the first direction, wherein the ground voltage line is electrically connected to the fifth metal layer on the second active area.

22. (canceled)

23. A method of forming a semiconductor structure, comprising:
providing a substrate, wherein the substrate includes at least one unit area, a unit area of the at least one unit area includes a first region and a second region adjacent to the first region, the first region and the second region are arranged along a first direction, the first region includes a first active area, a first isolation area, and a second active area arranged along a second direction, the first active area and the second active area are located on two sides of the first isolation area, the second region includes a third active area, a second isolation area, and a fourth active area arranged along the second direction, the third active area and a fourth active area are located on two sides of the second isolation area, and a central axis of the first isolation area parallel to the first direction does not coincide with a central axis of the second isolation area parallel to the first direction, the first direction is parallel to a surface of the substrate, and the first direction and the second direction are perpendicular to each other;
forming a first gate structure located on the first region, wherein the first gate structure spans the first active area, the first isolation area and the second active area; and a first metal layer and a second metal layer respectively located on two sides of the first gate structure, wherein the first gate structure, the first metal layer, and the second metal layer are parallel to the second direction;
forming a second gate structure located on the second region, wherein the second gate structure spans the third active area, the second isolation area and the fourth active area; and a third metal layer and a fourth metal layer respectively located on two sides of the second gate structure, wherein the second gate structure, the third metal layer and the fourth metal layer are parallel to the second direction;
forming a first isolation structure located on the first isolation area, wherein the first isolation structure penetrates the first metal layer and the second metal layer along the first direction, and the first gate structure is located over the first isolation structure; and
forming a second isolation structure located on the second isolation area, wherein the second isolation structure penetrates the third metal layer and the fourth metal layer along the first direction, and the second gate structure is located over the second isolation structure.
